(19) United States
(12) Patent Application Publication
(10) Pub. No.: US 2026/0210758 A1
(43) Pub. Date: Jul. 23, 2026

(54) SEMICONDUCTOR TESTING STRUCTURE

(71) Applicant: Ennostar Corporation, Hsinchu City (TW)

(72) Inventors: Wen-Chien WU, Hsinchu (TW); Wei-Shan HU, Hsinchu (TW); Ching-Tai CHENG, Hsinchu (TW); Min-Hsun HSIEH, Hsinchu (TW)

(21) Appl. No.: 19/451,955

(22) Filed: Jan. 16, 2026

(30) Foreign Application Priority Data
Jan. 23, 2025 (TW) 114103007

(51) Int. Cl. G01J 1/02; G01J 1/42

(52) U.S. Cl. CPC G01J 1/0223; G01J 2001/4252

(57) ABSTRACT

A semiconductor test structure includes a carrier; a conductive layer disposed on the carrier and including a continuous surface with a first region and a second region; a first adhesive portion and a second adhesive portion disposed on the conductive layer in a configuration of covering the first region and exposing the second region; and a first semiconductor device and a second semiconductor device disposed on the first adhesive portion and the second adhesive portion, respectively, wherein the first semiconductor device includes a first lower electrode, a first semiconductor stack, and a first upper electrode, in a cross-sectional view, the first lower electrode faces the first adhesive portion, the first upper electrode faces away from the first adhesive portion.

### REFERENCE TO RELATED APPLICATION

This application claims the right of priority based on TW Application Serial No. 114103007, filed on Jan. 23, 2025, and the content of which is hereby incorporated by reference in its entirety.

### TECHNICAL FIELD

The application relates to a semiconductor testing structure, and more particularly to the semiconductor testing structure for an electroluminescence testing of a vertical micro light-emitting diode and a fabricating method thereof.

### DESCRIPTION OF BACKGROUND ART

The semiconductor device such as the light-emitting diodes (LED) has the advantages including the low power consumption, the low heat generation, the long operational lifetime, the vibration resistance, the compact size, the fast response speed, and the favorable optoelectronic characteristics such as the stable emission wavelength. Accordingly, the LED is widely applied in the electronic devices such as the household appliances, the equipment indicator lights, and the displays.

A vertical micro light-emitting diode (vertical μLED) is a light-emitting diode structure having dimensions on the micrometer scale, with p-electrode and n-electrode disposed on opposite sides of the light-emitting layer. To test whether the electrical characteristics or the light-emitting characteristics of the light-emitting diode meet the predetermined specifications, the probes are typically used to contact the p-electrode and the n-electrode to perform the electroluminescence (EL) measurements. In manufacturing the various electronic devices, the multiple light-emitting diodes may be fixed onto a temporary substrate using a cured adhesive, and may be transferred between different temporary substrates or from a temporary substrate to a target substrate. However, since the lower electrode of the current vertical micro light-emitting diode is typically embedded in the cured adhesive, only the photoluminescence (PL) measurements can be performed on the vertical micro light-emitting diode, and the electroluminescence measurements are difficult to be measured. Because the optoelectronic characteristics measured by the photoluminescence measurements typically differ from those of the diode during actual use, this is disadvantageous for quality control of the vertical micro light-emitting diodes.

### SUMMARY OF THE APPLICATION

In view of the foregoing, the embodiments of the present disclosure provide a semiconductor test structure and a fabricating method thereof. The semiconductor test structure can be fabricated in a chip-on-carrier (COC) process and a chip-on-wafer (COW) process, and is configured to enable the electroluminescence measurement so as to overcome the problems encountered in the prior art.

According to an embodiment of the present disclosure, a semiconductor test structure includes a carrier, a conductive layer, a first adhesive portion, a second adhesive portion, a first semiconductor device, and a second semiconductor device. The conductive layer is disposed on the carrier and includes a continuous surface. the continuous surface includes a first region and a second region. The first adhesive portion and the second adhesive portion are disposed on the conductive layer in a configuration of covering the first region and expose the second region. The first semiconductor device and the second semiconductor device are disposed on the first adhesive portion and the second adhesive portion, respectively, wherein the first semiconductor device includes a first lower electrode, a first semiconductor stack, and a first upper electrode. In a cross-sectional view, the first lower electrode faces the first adhesive portion, the first upper electrode faces away from the first adhesive portion.

### BRIEF DESCRIPTION OF THE DRAWINGS

For ease of understanding, the drawings and the detailed descriptions thereof may be referred to concurrently when reading the present disclosure. Through the specific embodiments described herein and with reference to the corresponding drawings, the specific embodiments of the present disclosure are explained in detail to illustrate the operating principles thereof. In addition, for clarity, the features in the drawings may not be depicted to scale; therefore, the dimensions of certain features in some drawings may be intentionally exaggerated or reduced.

FIGS. 1, 2, and 3 illustrate the cross-sectional schematic views of the semiconductor test structure according to some embodiments of the present disclosure.

FIG. 4 illustrates a top schematic view of the semiconductor test structure according to some embodiments of the present disclosure.

FIGS. 5, 6, and 7 illustrate the cross-sectional schematic views of process stages for fabricating the semiconductor test structure in a chip-on-carrier (COC) process according to an embodiment of the present disclosure, wherein FIG. 5 illustrates a top schematic view of the process stage.

FIGS. 8, 9, and 10 illustrate the cross-sectional schematic views of the process stages for fabricating the semiconductor test structure in the chip-on-carrier (COC) process according to another embodiment of the present disclosure.

FIG. 11 illustrates a cross-sectional schematic view of the process stages for fabricating the semiconductor test structure in the chip-on-wafer (COW) process according to another embodiment of the present disclosure.

### DETAILED DESCRIPTION OF PREFERRED EMBODIMENTS

The present disclosure provides several different embodiments that may be used to implement various features of the present disclosure. For the sake of simplicity, the present disclosure also describes examples of specific components and arrangements. The purpose of providing these embodiments is merely illustrative and is not intended to impose any limitation. Various embodiments in the present disclosure may use repeated reference numerals and/or textual annotations. The use of such repeated reference numerals and annotations is intended to make the description more concise and clear, and is not intended to indicate any relationship between different embodiments and/or configurations.

In addition, spatially relative terms used in the present disclosure, such as “under”, “lower”, “below”, “above”, “on”, “upper”, “top”, “bottom”, and similar terms, are used for ease of description to describe the relative relationship between one element or feature and another (or multiple) element(s) or feature(s) in the figures. Apart from the orientation shown in the figures, these spatially relative terms are also used to describe the orientation of the elements in use and during operation. As the orientation of the element changes (e.g., rotated by 90 degrees or to other orientations), the corresponding spatial descriptions are to be interpreted in a similar manner.

Although the present disclosure uses the terms first, second, third, and so forth to describe elements, components, regions, layers, and/or sections, it should be understood that such elements, components, regions, layers, and/or sections are not to be limited by these terms. These terms are only used to distinguish one element, component, region, layer, and/or section from another, and do not imply any sequential order, nor do they indicate the arrangement order between the elements or the sequence in manufacturing processes. Therefore, without departing from the scope of the specific embodiments of the present disclosure, an element, component, region, layer, or section described as “first” herein may also be referred to as a “second” element, component, region, layer, or section.

The terms “about” or “substantially” as referred to in the present disclosure generally indicate within 20% of a given value or range, preferably within 10%, more preferably within 5%, or within 3%, 2%, 1%, or 0.5%. It should be noted that the numerical values provided in the specification are approximate values, meaning that even in the absence of explicit use of the terms “about” or “substantially,” such meanings may be implied.

The terms “coupled,” “coupling,” or “electrically connected” as referred to in the present disclosure include any direct or indirect electrical connection means. For example, when the text describes a first component as being coupled to a second component, it means that the first component may be directly electrically connected to the second component, or indirectly electrically connected to the second component via other devices or connecting means.

Although the following description of the present disclosure is provided using specific embodiments, the principles of the present disclosure may also be applied to other embodiments. Furthermore, to avoid obscuring the spirit of the present invention, certain details are omitted, and such omitted details fall within the knowledge of those skilled in the relevant art.

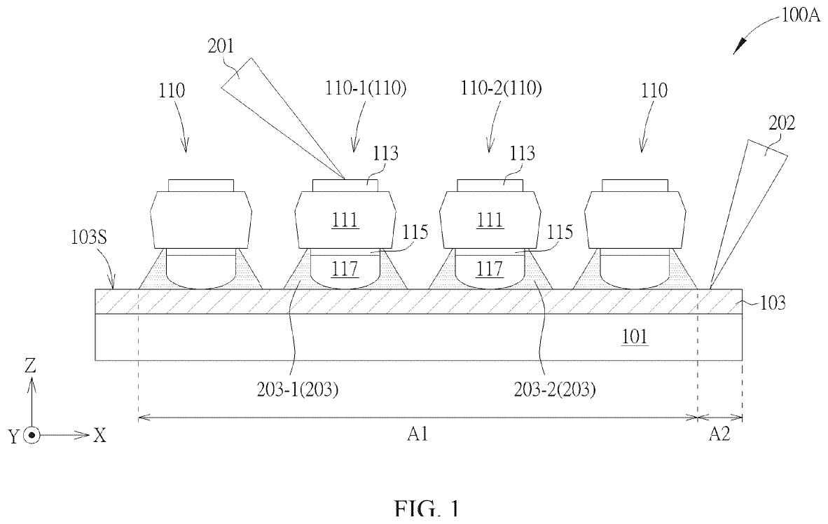

FIG. 1 illustrates a cross-sectional schematic view of a semiconductor test structure 100A according to an embodiment of the present disclosure. The semiconductor test structure 100A includes a carrier 101, a conductive layer 103, a plurality of semiconductor devices 110, and a plurality of adhesive portions 203. The conductive layer 103 is disposed on the carrier 101 and includes a continuous surface 103S. The plurality of adhesive portions 203 is disposed on the conductive layer 103, covers a first region A1 of the continuous surface 103S and exposes a second region A2 of the continuous surface 103S. In an embodiment, the plurality of adhesive portions 203 may be laterally separated from each other on the conductive layer 103, wherein “laterally” refers to a direction along the X-axis and/or Y-axis shown in FIG. 1. In another embodiment, the plurality of adhesive portions 203 may be laterally connected to each other on the conductive layer 103, covers the first region A1 of the continuous surface 103S and exposes the second region A2 of the continuous surface 103S. The plurality of semiconductor devices 110 is disposed on the carrier 101 and the conductive layer 103, and each semiconductor device 110 is disposed on an adhesive portion 203. The semiconductor device 110 may include the transistor device or the semiconductor light-emitting device, such as the vertical micro light-emitting diode, but is not limited thereto.

The adhesive portion 203 includes a polymer. According to the embodiment, the adhesive portion 203 may include polyimide (PI), polyepoxide (EPO), polybenzoxazole (PBO), polysiloxane, cyclic olefin polymer (COP), or benzocyclobutene (BCB), but is not limited thereto.

According to some embodiments of the present disclosure, the carrier 101 is provided to support the conductive layer 103 and the plurality of semiconductor devices 110 disposed thereon, and the carrier 101 and the conductive layer 103 are transmittable to light emitted from the semiconductor devices 110, which is easy for the observation of whether the semiconductor device 110 is illuminated during the electroluminescence measurement. The carrier 101 may be a non-epitaxial material or a non-growth substrate, such as a ceramic substrate, a metal substrate, a glass substrate, a thermal release tape, a UV release tape, a chemical release tape, a heat-resistant tape, a blue tape, or a tape with a dynamic release layer (DRL). In an embodiment, the carrier 101 may be a glass substrate, a sapphire substrate, or a quartz substrate.

The conductive layer 103 includes a transparent metal oxide or a thin metal layer capable of forming an ohmic contact with a semiconductor layer of the semiconductor device 110. The transparent metal oxide includes indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium cerium oxide (ICO), indium tungsten oxide (IWO), indium titanium oxide (ITiO), zinc oxide (ZnO), indium zinc oxide (IZO), indium gallium oxide (IGO), or gallium aluminum zinc oxide (GAZO). In an embodiment, the conductive layer 103 may be an indium tin oxide (ITO) layer.

The carrier 101 and the conductive layer 103 include a material that is transparent for the laser light or the incoherent light, which enables the semiconductor device 110 to be separated from the carrier 101 and the conductive layer 103 by a laser lift-off (LLO) process. In an embodiment, when the LLO process is performed, if the adhesive portion 203 is disposed on the front side of the carrier 101, the laser light can be incident from the back side of the carrier 101, pass through the carrier 101, be irradiated onto the adhesive portion 203, and then pass through the front side of the carrier 101.

The plurality of semiconductor devices 110 includes a first semiconductor device 110-1, a second semiconductor device 110-2, and an m-th semiconductor device, wherein m is a positive integer greater than 2. The plurality of semiconductor devices 110 may have different, identical, or similar structures and sizes. In a cross-sectional view, the first semiconductor device 110-1 and the second semiconductor device 110-2 are laterally separated from each other, and the continuous surface 103S of the conductive layer 103 has a portion which is located between the first semiconductor device 110-1 and the second semiconductor device 110-2.

In an embodiment, each semiconductor device 110 includes a light-emitting device, and the first semiconductor device 110-1 includes a semiconductor stack 111, an upper electrode 113, and a lower electrode 115. In the cross-sectional view, the lower electrode 115 faces the first adhesive portion 203-1, and the upper electrode 113 faces away from the first adhesive portion 203-1. The first semiconductor device 110-1 further includes a conductive bump 117 disposed between the lower electrode 115 and the conductive layer 103. The conductive bump 117 includes a convex portion facing and protruded towards the conductive layer 103, and the convex portion of the conductive bump 117 has a portion which is in direct contact with the conductive layer 103, thereby establishing the electrical connection between the lower electrode 115 and the conductive layer 103. The second semiconductor device 110-2 includes the same or similar structure as the first semiconductor device 110-1, and includes the semiconductor stack 111, the upper electrode 113, the lower electrode 115, and the conductive bump 117. In the cross-sectional view, the lower electrode 115 faces the second adhesive portion 203-2, and the upper electrode 113 faces away from the second adhesive portion 203-2. In addition, the lower electrode 115 also faces the carrier 101 and the conductive layer 103, while the upper electrode 113 faces away from the carrier 101 and the conductive layer 103. The first adhesive portion 203-1 and the second adhesive portion 203-2 fix the first semiconductor device 110-1 and the second semiconductor device 110-2 to the conductive layer 103, respectively. The semiconductor stack 111 has a sidewall which is not directly connected to the first adhesive portion 203-1 and/or the second adhesive portion 203-2. The first adhesive portion 203-1 and the second adhesive portion 203-2 cover the side surfaces of the lower electrode 115 and the conductive bump 117, as well as part of the bottom surface of the semiconductor stack 111.

In an embodiment, the semiconductor stack 111 includes a p-type semiconductor layer, a multiple quantum well (MQW), and an n-type semiconductor layer sequentially stacked from the bottom to the top. The lower electrode 115 is a p-type electrode and contacts the p-type semiconductor layer, and the upper electrode 113 is an n-type electrode and contacts the n-type semiconductor layer, but the disclosure is not limited thereto. In another embodiment, the semiconductor stack 111 includes the n-type semiconductor layer, the multiple quantum well (MQW), and the p-type semiconductor layer sequentially stacked from the bottom to the top. The lower electrode 115 is the n-type electrode and contacts the n-type semiconductor layer, and the upper electrode 113 is the p-type electrode and contacts the p-type semiconductor layer. In an embodiment, the lower electrode 115 includes a metal, such as chromium (Cr), nickel (Ni), gold (Au), titanium (Ti), platinum (Pt), aluminum (Al), tin (Sn), or a combination thereof. The upper electrode 113 includes a transparent conductive oxide, such as indium tin oxide (ITO), indium oxide (InO), tin oxide (SnO), or another suitable transparent conductive material. The conductive bump 117 includes solder.

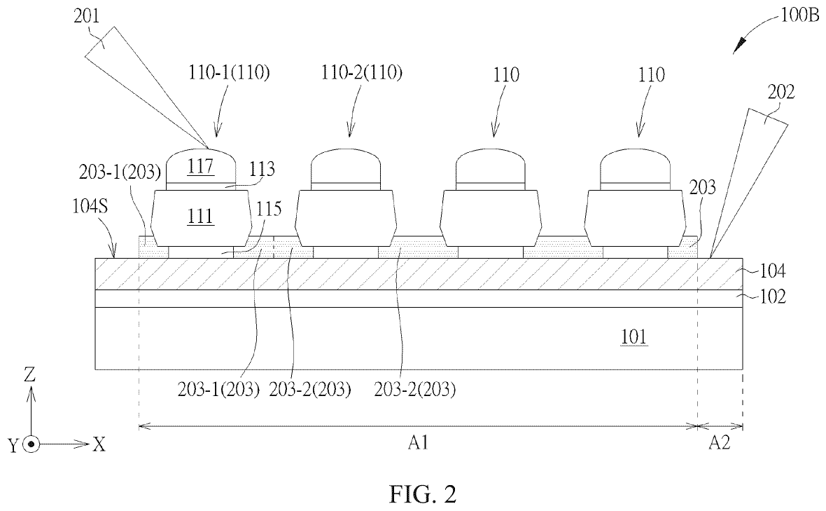

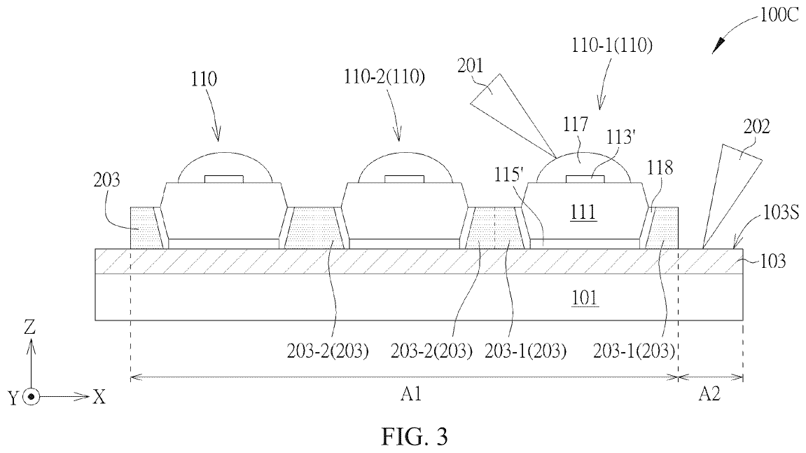

According to some embodiments of the present disclosure, each semiconductor device 110 includes a light-emitting surface and a non-light-emitting surface disposed opposite to each other, and the electrode located on the light-emitting surface has higher light transmittance than that of the electrode located on the non-light-emitting surface and that of the conductive bump 117. In the embodiment shown in FIG. 1, the light-emitting surface of the semiconductor device 110 faces away from the carrier 101, and the non-light-emitting surface faces toward the carrier 101. In other embodiments, as shown in FIGS. 2 and 3, the light-emitting surface of the semiconductor device 110 faces toward the carrier 101, and the non-light-emitting surface faces away from the carrier 101.

As shown in FIG. 1, when performing the electroluminescence measurement on the semiconductor test structure 100A, a first probe 201 may directly or indirectly contact the upper electrode 113 of the semiconductor device 110 in the semiconductor test structure 100A, and a second probe 202 may directly or indirectly contact the conductive layer 103. The first probe 201 may directly apply a first voltage to the upper electrode 113, and the second probe 202 may apply a second voltage (the second voltage is different from the first voltage) to the conductive layer 103 through the second region A2 exposed from the continuous surface 103S. The second voltage is transmitted from the second probe 202 to the lower electrode 115 via the conductive layer 103 and the conductive bump 117. According to some embodiments of the present disclosure, the second probe 202 does not need to directly contact the conductive bump 117 or the lower electrode 115 of the semiconductor device 110 to process the electroluminescence measurement. Therefore, even the lower electrode 115 of the semiconductor device 110 is embedded in the adhesive portion 203, the electroluminescence measurement can still be performed on the semiconductor device 110 and is not limited to the photoluminescence measurement.

FIG. 2 illustrates a cross-sectional schematic view of a semiconductor test structure 100B according to another embodiment of the present disclosure. The semiconductor test structure 100B includes the carrier 101, an adhesive layer 102, a film-type conductive layer 104, the plurality of semiconductor devices 110, and the plurality of adhesive portions 203. The film-type conductive layer 104, the adhesive layer 102, and the carrier 101 are transmittable to light emitted from the semiconductor devices 110, which is easy for the observation of whether the semiconductor devices 110 are illuminated during the electroluminescence measurement. The film-type conductive layer 104 includes a multilayer structure including a base film and a conductive transparent metal oxide layer, wherein the transparent metal oxide layer directly contacts the lower electrode 115 of the semiconductor device 110, and the base film is adjacent to the adhesive layer 102. The adhesive layer 102 is disposed between the film-type conductive layer 104 and the carrier 101 to attach the film-type conductive layer 104 onto the carrier 101. In an embodiment, the transparent metal oxide layer of the film-type conductive layer 104 includes an indium tin oxide (ITO) layer. The base film has sufficient mechanical strength to support the transparent metal oxide layer and includes polyethylene terephthalate (PET) for example. The adhesive layer 102 includes an optical clear adhesive (OCA), but is not limited thereto. The adhesive layer 102 and the film-type conductive layer 104 include a material that can be penetrated by the laser light or the incoherent light, thereby the semiconductor device 110 can be separated from the film-type conductive layer 104 by the laser lift-off (LLO) process.

The plurality of semiconductor devices 110 includes the first semiconductor device 110-1, the second semiconductor device 110-2, and an m-th semiconductor device, wherein m is a positive integer greater than 2. In a cross-sectional view, the first semiconductor device 110-1 and the second semiconductor device 110-2 are laterally separated from each other. In an embodiment, each semiconductor device 110 may have different, identical, or similar structures and sizes, and includes the semiconductor stack 111, the upper electrode 113, the lower electrode 115, and the conductive bump 117. The conductive bump 117 is disposed on the upper electrode 113 and directly contacts the upper electrode 113, while the lower electrode 115 directly contacts the film-type conductive layer 104, thereby establishing the electrical connection between the lower electrode 115 and the film-type conductive layer 104. In an embodiment, the semiconductor stack 111 includes the n-type semiconductor layer, the multiple quantum well (MQW), and the p-type semiconductor layer sequentially stacked from the bottom to the top. The lower electrode 115 is an n-type electrode and contacts the n-type semiconductor layer, and the upper electrode 113 is the p-type electrode and contacts the p-type semiconductor layer, but the disclosure is not limited thereto. In another embodiment, the semiconductor stack 111 includes the p-type semiconductor layer, the multiple quantum well (MQW), and the n-type semiconductor layer sequentially stacked from the bottom to the top. The lower electrode 115 may be the p-type electrode and contacts the p-type semiconductor layer, and the upper electrode 113 may be the n-type electrode and contacts the n-type semiconductor layer. In an embodiment, the lower electrode 115 includes a transparent layer including the transparent metal oxide, such as indium tin oxide (ITO), indium oxide (InO), tin oxide (SnO), or another suitable transparent conductive material. The lower electrode 115 is disposed between the semiconductor stack 111 and the film-type conductive layer 104, wherein the transparent layer of the lower electrode 115 is embedded in the adhesive portion 203 and directly contacts the film-type conductive layer 104. The upper electrode 113 includes the metal, such as chromium (Cr), nickel (Ni), gold (Au), titanium (Ti), platinum (Pt), aluminum (Al), tin (Sn), or a combination thereof. The conductive bump 117 includes solder. In a cross-sectional view, the lower electrode 115 faces the adhesive portion 203 and the upper electrode 113 faces away from the adhesive portion 203. In addition, the lower electrode 115 also faces the carrier 101 and the film-type conductive layer 104, while the upper electrode 113 faces away from the carrier 101 and the film-type conductive layer 104.

The film-type conductive layer 104 includes a continuous surface 104S. In an embodiment, the plurality of adhesive portions 203 is laterally connected to each other and disposed on the film-type conductive layer 104, covers the first region A1 of the continuous surface 104S and exposes the second region A2 of the continuous surface 104S. The plurality of adhesive portions 203 includes a first adhesive portion 203-1 and a second adhesive portion 203-2 laterally connected to each other, which fix the first semiconductor device 110-1 and the second semiconductor device 110-2 to the film-type conductive layer 104, respectively. Each adhesive portion 203 covers the side surfaces of the lower electrode 115, part of the bottom surface of the semiconductor stack 111, and part of the sidewalls of the semiconductor stack 111, and each adhesive portion 203 directly contacts the sidewalls of the semiconductor stack 111.

As shown in FIG. 2, the first probe 201 and the second probe 202 contact the conductive bump 117 of the semiconductor device 110 and the film-type conductive layer 104 of the semiconductor test structure 100B, respectively. The first probe 201 may apply a first voltage to the upper electrode 113 via the conductive bump 117 and the second probe 202 may apply a second voltage to the film-type conductive layer 104 in the second region A2 exposed from the continuous surface 104S and the second voltage is transmitted to the lower electrode 115 through the film-type conductive layer 104. According to some embodiments of the present disclosure, the second probe 202 does not need to directly contact the lower electrode 115 of the semiconductor device 110 to process the electroluminescence measurement. Therefore, even if the lower electrode 115 of the semiconductor device 110 is embedded in the adhesive portion 203, the semiconductor device 110 can still be tested by the electroluminescence measurement, and the measurement is not limited to the photoluminescence measurement. Other detailed features of the semiconductor test structure 100B shown in FIG. 2 can be referred to the detailed description of the semiconductor test structure 100A of FIG. 1 and will not be repeated herein.

FIG. 3 illustrates a cross-sectional schematic view of a semiconductor test structure 100C according to another embodiment of the present disclosure. The semiconductor test structure 100C includes the carrier 101, the conductive layer 103, the plurality of semiconductor devices 110, and the plurality of adhesive portions 203. The plurality of semiconductor devices 110 includes the first semiconductor device 110-1, the second semiconductor device 110-2, and an m-th semiconductor device, wherein m is a positive integer greater than 2. In the cross-sectional view, the first semiconductor device 110-1 and the second semiconductor device 110-2 are laterally separated from each other. In an embodiment, each semiconductor device 110 may include the same or similar structure and size, and includes the semiconductor stack 111, an upper electrode 113′, a lower electrode 115′, the conductive bump 117, and a protective layer 118. The conductive bump 117 is disposed on the upper electrode 113′, covers and contacts the upper electrode 113′. The lower electrode 115′ is disposed on the bottom surface of the semiconductor stack 111 and directly contacts the conductive layer 103. The protective layer 118 covers the side surfaces of the lower electrode 115′ and part of the sidewalls of the semiconductor stack 111.

In an embodiment, the semiconductor stack 111 includes the p-type semiconductor layer, the multiple quantum well (MQW), and the n-type semiconductor layer sequentially stacked from the bottom to the top. The lower electrode 115′ is the p-type electrode and contacts the p-type semiconductor layer, and the upper electrode 113′ is the n-type electrode and contacts the n-type semiconductor layer, but the disclosure is not limited thereto. In another embodiment, the semiconductor stack 111 includes the n-type semiconductor layer, the multiple quantum well (MQW), and the p-type semiconductor layer sequentially stacked from the bottom to the top. The lower electrode 115′ is the n-type electrode and contacts the n-type semiconductor layer, and the upper electrode 113′ is the p-type electrode and contacts the p-type semiconductor layer. In an embodiment, the lower electrode 115′ includes the transparent metal oxide, such as indium tin oxide (ITO), indium oxide (InO), tin oxide (SnO), or another suitable transparent conductive material. The upper electrode 113′ includes a metal, such as chromium (Cr), nickel (Ni), gold (Au), titanium (Ti), platinum (Pt), aluminum (Al), tin (Sn), or a combination thereof. The conductive bump 117 includes solder. In the cross-sectional view, the lower electrode 115′ faces the adhesive portion 203, and the upper electrode 113′ faces away from the adhesive portion 203. In addition, the lower electrode 115′ also faces the carrier 101 and the conductive layer 103, while the upper electrode 113′ faces away from the carrier 101 and the conductive layer 103.

The conductive layer 103 includes the continuous surface 103S. In an embodiment, the plurality of adhesive portions 203 is laterally connected to each other and disposed on the conductive layer 103, covers the first region A1 of the continuous surface 103S and exposes the second region A2 of the continuous surface 103S. The plurality of adhesive portions 203 includes the first adhesive portion 203-1 and the second adhesive portion 203-2 laterally connected to each other, which fix the first semiconductor device 110-1 and the second semiconductor device 110-2 to the conductive layer 103, respectively. Each adhesive portion 203 covers the side surfaces of the lower electrode 115′ and part of the sidewalls of the semiconductor stack 111, wherein the protective layer 118 is disposed between the adhesive portion 203 and the semiconductor stack 111, and between the adhesive portion 203 and the lower electrode 115′. The protective layer 118 includes an insulating material or dielectric material, such as silicon oxide, silicon nitride, silicon oxynitride, or a combination thereof.

As shown in FIG. 3, the first probe 201 and the second probe 202 may be used to contact the conductive bump 117 of the semiconductor device 110 and the conductive layer 103 of the semiconductor test structure 100C, respectively. The first probe 201 may apply a first voltage to the upper electrode 113′ via the conductive bump 117 and the second probe 202 may apply a second voltage to the conductive layer 103 in the second region A2 exposed from the continuous surface 103S, and the second voltage can be transmitted to the lower electrode 115′ from the conductive layer 103. According to some embodiments of the present disclosure, the second probe 202 does not need to directly contact the lower electrode 115′ of the semiconductor device 110 to process the electroluminescence measurement. Therefore, even if the lower electrode 115′ of the semiconductor device 110 is embedded in the adhesive portion 203, the semiconductor device 110 can still be tested by the electroluminescence measurement without limiting to the photoluminescence measurement. Other detailed features of the semiconductor test structure 100C shown in FIG. 3 can be referred to the detailed description of the semiconductor test structure 100A of FIG. 1, and that will not be repeated herein. In the embodiment, the adhesive portion 203 covers most of the sidewalls of the semiconductor stack 111, prevents the semiconductor device 110 from shifting when the first probe 201 contacts the conductive bump 117. Therefore, the semiconductor test structure 100C can provide a more robust test structure to withstand the probe pressure from the first probe 201.

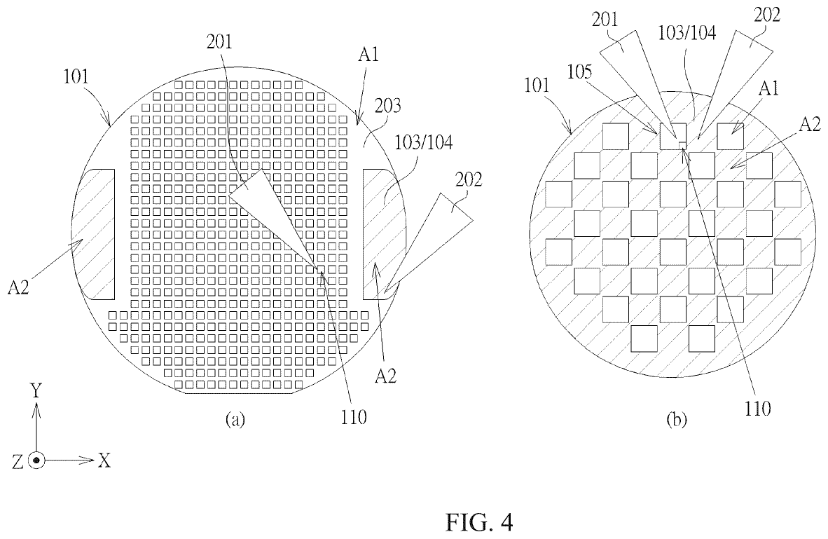

FIG. 4 illustrates a top schematic view of the semiconductor test structures according to some embodiments of the present disclosure. These semiconductor test structures may be the semiconductor test structure 100A, 100B, or 100C shown in FIGS. 1, 2, and 3. As shown in FIG. 4(a), in an embodiment, the plurality of semiconductor devices 110 of the semiconductor test structure may be densely arranged in an array on the carrier 101. The conductive layer 103 or the film-type conductive layer 104 is disposed on the carrier 101, and the adhesive portion 203 covers the first region A1 of the conductive layer 103 or the film-type conductive layer 104, while exposing the second region A2. In an embodiment, the second region A2 may be located on the left and right sides of the array of the plurality of semiconductor devices 110. The adhesive portion 203 fixes the plurality of semiconductor devices 110 to the conductive layer 103 or the film-type conductive layer 104. In some embodiments, the lower electrodes or the conductive bumps located on the lower side of the semiconductor devices 110 are embedded in the adhesive portion 203, and the lower electrodes or conductive bumps located on the lower side directly contact the conductive layer 103 or the film-type conductive layer 104, while the upper electrodes or the conductive bumps located on the upper side are not covered by the adhesive portion 203. During the electroluminescence measurement, the first probe 201 contacts the upper electrode or the conductive bump on the upper side of the semiconductor device 110, and the second probe 202 contacts the second region A2 of the conductive layer 103 or the film-type conductive layer 104 exposed from the adhesive portion 203.

As shown in FIG. 4(b), in another embodiment, the plurality of semiconductor devices 110 of the semiconductor test structure may be arranged on the carrier 101 in a block pattern with spaces therebetween, wherein each block 105 includes a matrix of multiple semiconductor devices 110. In an embodiment, the multiple blocks 105 can be arranged in a checkerboard configuration by selecting multiple blocks of semiconductor elements 110 to be transferred and arranging them at intervals on the carrier 101. The conductive layer 103 or the film-type conductive layer 104 is disposed on the carrier 101, and the adhesive portion (not shown) covers the first region A1 of the conductive layer 103 or the film-type conductive layer 104 while exposing the second region A2. In an embodiment, multiple second regions A2 may be located on the left and right sides and the upper and lower sides of one block 105. During the electroluminescence measurement, the first probe 201 contacts the upper electrode or the conductive bump located on the upper side of the semiconductor device 110, and the second probe 202 contacts the conductive layer 103 or the film-type conductive layer 104 exposed in the second region A2. In the embodiment, each block 105 is adjacent to at least one second region A2, thereby the current path is shortened during the electroluminescence measurement and the testing is more easily processed. Furthermore, the checkerboard arrangement of multiple second regions A2 can expose more surface area of the conductive layer 103 or the film-type conductive layer 104, making it easier for the second probe 202 to contact the conductive layer 103 or the film-type conductive layer 104 for testing. In sampling tests, the same-position semiconductor device 110 in each block 105 and the adjacent second region A2 are selected for the electroluminescence measurement, thereby improving the consistency in the electroluminescence measurement.

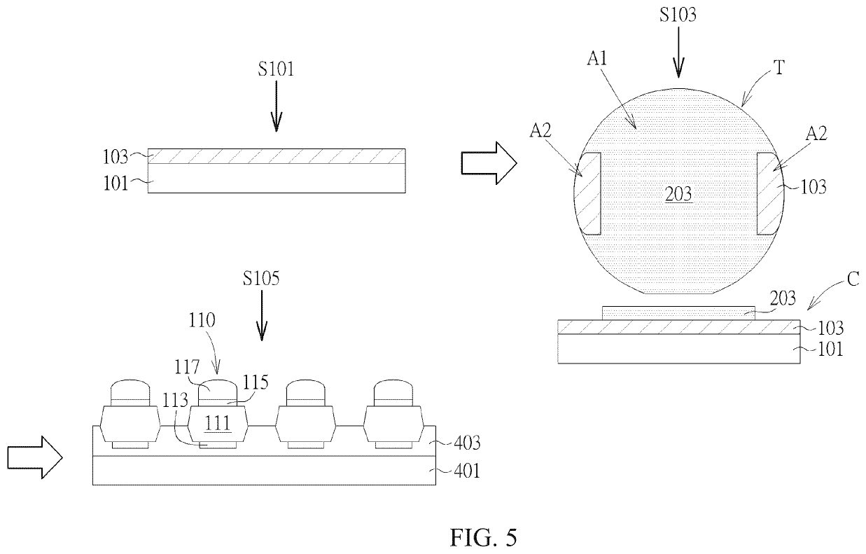

FIGS. 5, 6, and 7 illustrate cross-sectional schematic views of the semiconductor test structure 100A fabricated in different process stages by using the chip-on-carrier (COC) process according to an embodiment of the present disclosure, wherein FIG. 5 also illustrates a top schematic view of a process stage. Referring to FIG. 5, in the step S101, the carrier 101 is first provided, and the conductive layer 103 is formed on the carrier 101. The conductive layer 103 completely covers the carrier 101 and includes the continuous surface 103S. In an embodiment, the carrier 101 includes a sapphire substrate, and the conductive layer 103 includes indium tin oxide (ITO). In another embodiment, the carrier 101 and the conductive layer 103 may be provided with a glass substrate having an indium tin oxide (ITO) layer formed thereon.

Continuing to refer to FIG. 5, in the step S103, as shown in the cross-sectional view C, the adhesive portion 203 is formed on the conductive layer 103. As shown in top view T, the adhesive portion 203 covers the first region A1 of the continuous surface 103S of the conductive layer 103 and the second region A2 is exposed, wherein the second region A2 is located on the left and right sides of the first region A1. In an embodiment, the adhesive portion 203 may be formed by using the spin coating, the soft baking and the patterning process, and the adhesive portion 203 includes polyimide (PI) or polyepoxide (EPO).

Next, still referring to FIG. 5, in the step S105, the plurality of semiconductor devices 110 are provided and fixed to a substrate 401 using a glue 403. In an embodiment, the substrate 401 includes a sapphire substrate, and the adhesive 403 includes benzocyclobutene (BCB). Each semiconductor device 110 may include the semiconductor stack 111, the upper electrode 113, the lower electrode 115, and the conductive bump 117, wherein the upper electrode 113 and part of the sidewalls of the semiconductor stack 111 are embedded in the glue 403. The details of these features of the semiconductor device 110 may be referred to in the detailed description of the semiconductor test structure 100A of FIG. 1, and that will not be repeated herein.

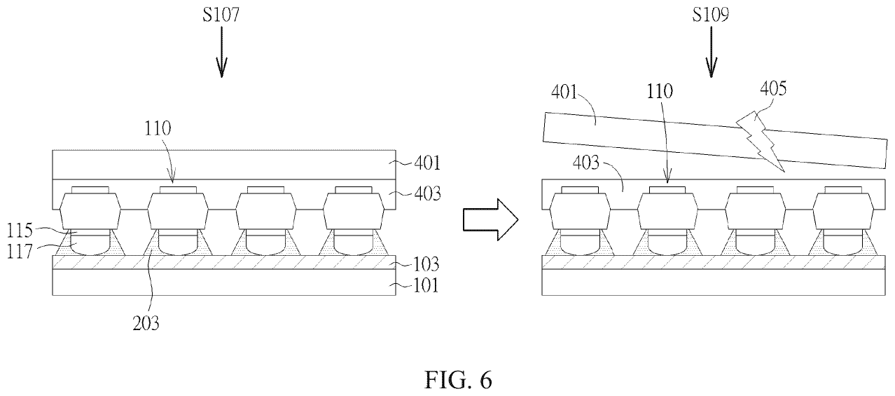

Then, referring to FIG. 6, in the step S107, the structure provided in the step S105 is flipped upside down and bonded to the structure provided in the step S103, wherein the lower electrode 115 and the conductive bump 117 of the semiconductor device 110 faces the adhesive portion 203. In the step S107, a bonding process with pressure applied from both top and bottom is used to bond the plurality of semiconductor devices 110 on the substrate 401 to the conductive layer 103 on the carrier 101. Because the adhesive portion 203 on the conductive layer 103 provided in the step S103 includes a thinner thickness, the cohesive force is between the adhesive portion 203 and the lower electrode 115 and the conductive bump 117. After the bonding process provided in the step S107, the adhesive portion 203 gathers around the lower electrode 115 and the conductive bump 117, thereby forming multiple adhesive portions 203 that are laterally separated from each other, and the convex portion of the conductive bump 117 directly contacts the conductive layer 103. Continuing to refer to FIG. 6, in the step S109, a laser lift-off (LLO) process may be performed by irradiating the laser light 405 from the back side of the substrate 401 to decompose or vaporize the glue 403, thereby separating the substrate 401 from the semiconductor devices 110, and the glue 403 remains on the semiconductor devices 110.

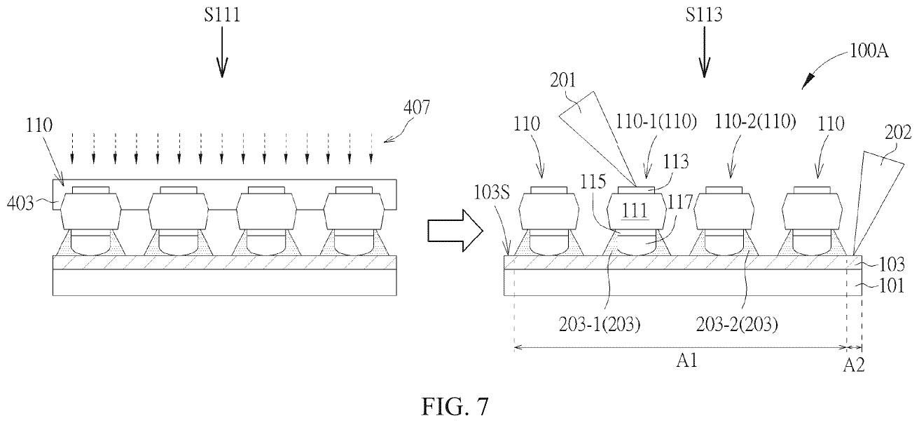

Thereafter, referring to FIG. 7, in the step S111, an etching process 407, such as an inductively coupled plasma (ICP) etching process, may be used to remove all of the glue 403. Continuing to refer to FIG. 7, in the step S113, after removing the glue 403, the upper electrode 113 of the semiconductor device 110 is exposed, thereby forming the semiconductor test structure 100A. The first probe 201 and the second probe 202 are used to contact the upper electrode 113 of the semiconductor device 110 and the second region A2 of the conductive layer 103 exposed from the adhesive portion 203, respectively, to perform the electroluminescence measurement.

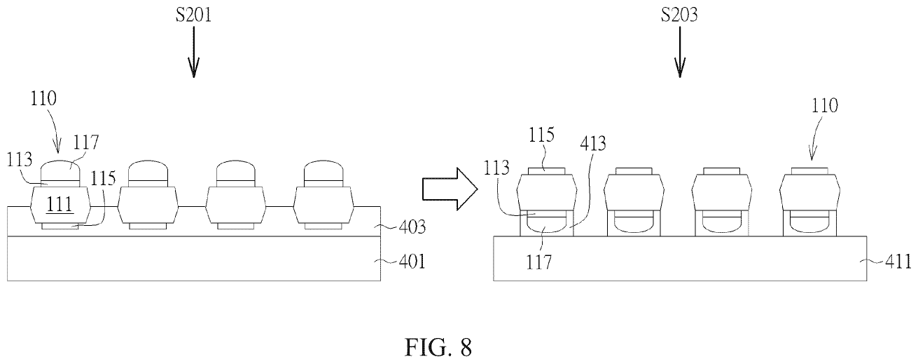

FIGS. 8, 9, and 10 illustrate the cross-sectional schematic views of different process stages for fabricating the semiconductor test structure 100B using a chip-on-carrier (COC) process according to another embodiment of the present disclosure. Referring to FIG. 8, in the step S201, the plurality of semiconductor devices 110 are first provided and fixed to the substrate 401 using the glue 403. In an embodiment, the substrate 401 includes the sapphire substrate, and the glue 403 includes benzocyclobutene (BCB). Each semiconductor device 110 includes the semiconductor stack 111, the upper electrode 113, the lower electrode 115, and the conductive bump 117, wherein the lower electrode 115 and part of the sidewalls of the semiconductor stack 111 are embedded in the glue 403.

Continuing to refer to FIG. 8, in the step S203, the structure illustrated in the step S201 is flipped upside down, and a bonding adhesive 413 is used to bond the semiconductor device 110 to another substrate 411, wherein the upper electrode 113 and the conductive bump 117 of the semiconductor device 110 are embedded in the bonding adhesive 413. Then, a laser lift-off (LLO) process may be performed by irradiating the laser light from the back side of the substrate 401 to decompose or vaporize the glue 403, thereby separating the substrate 401 from the semiconductor devices 110, with the glue 403 remaining on the semiconductor devices 110. Next, an etching process, such as an inductively coupled plasma (ICP) etching process, may be performed to remove all of the glue 403, thereby exposing the lower electrode 115 of the semiconductor device 110.

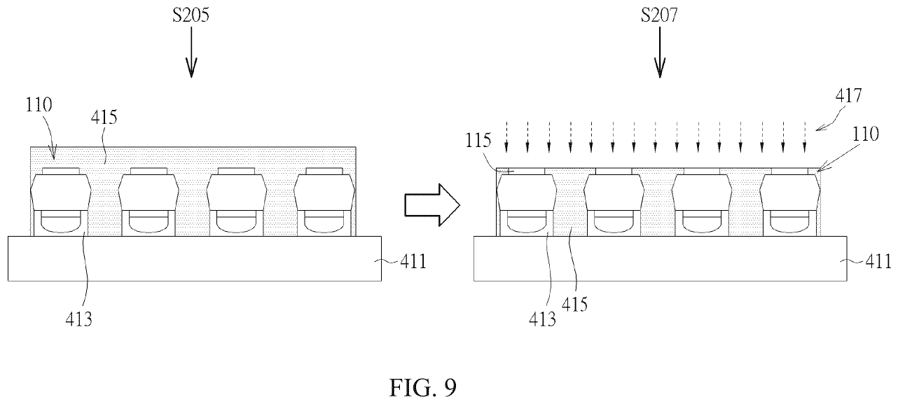

Thereafter, referring to FIG. 9, in the step S205, an adhesive 415 is formed on the substrate 411, and the semiconductor devices 110 are embedded in the adhesive 415. In an embodiment, the adhesive 415 may be provided in the form of a dry film, and an imprint bonding process may be used to embed the semiconductor devices 110 in the adhesive 415. Continuing to refer to FIG. 9, in the step S207, an etching process 417, such as an inductively coupled plasma (ICP) etching process or another dry etching process, may be performed to remove part of the adhesive 415, thereby reducing the top surface height of the adhesive 415 until the lower electrode 115 of the semiconductor device 110 is exposed.

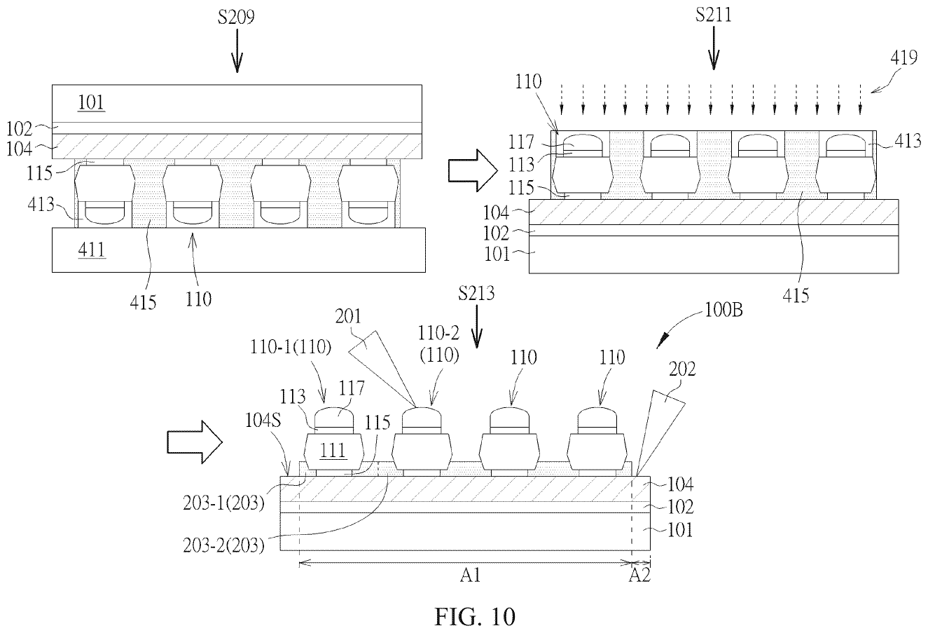

Next, referring to FIG. 10, in the step S209, the carrier 101 is provided, and the film-type conductive layer 104 is attached to the carrier 101 through the adhesive layer 102. Then, the adhesive 415 is used to bond the film-type conductive layer 104 to the semiconductor devices 110 on the substrate 411, wherein the film-type conductive layer 104 is in direct contact with the lower electrode 115 of the semiconductor device 110. Continuing to refer to FIG. 10, in the step S211, the structure illustrated in the step S209 is flipped upside down, and the laser lift-off (LLO) process is performed by irradiating the laser light from the back side of the substrate 411 to decompose or vaporize the bonding adhesive 413, thereby separating the substrate 411 from the semiconductor devices 110, with the bonding adhesive 413 remaining on the semiconductor devices 110. Next, an etching process 419, such as a dry etching process, may be performed to remove all of the bonding adhesive 413 and most of the adhesive 415.

Still referring to FIG. 10, in the step S213, after removing the bonding adhesive 413 and most of the adhesive 415, the upper electrode 113, the conductive bump 117, and part of the sidewalls of the semiconductor stack 111 of the semiconductor devices 110 are exposed, thereby forming the semiconductor test structure 100B, wherein the remaining adhesive 415 serves as the adhesive portion 203. The first probe 201 and the second probe 202 are used to contact the conductive bump 117 of the semiconductor device 110 and the second region A2 of the film-type conductive layer 104 exposed from the adhesive portion 203, respectively, to perform the electroluminescence measurement. In the embodiment, the film-type conductive layer 104 is attached to the carrier 101 through the adhesive layer 102, which provides a more convenient and faster manufacturing process. Furthermore, during the steps S209 to S213, no thermal process is required, thereby ensuring that the electrical properties of the film-type conductive layer 104 are not affected.

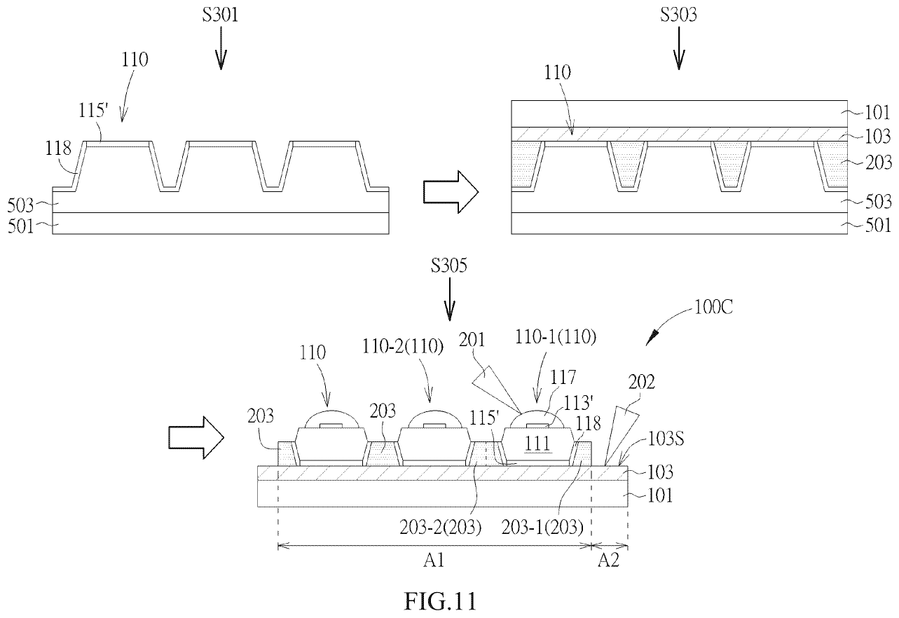

FIG. 11 illustrates a cross-sectional schematic view of different process stages for fabricating the semiconductor test structure 100C using a chip-on-wafer (COW) process according to another embodiment of the present disclosure. Referring to FIG. 11, in the step S301, a semiconductor stack 503 is epitaxially grown on a wafer 501, and the semiconductor stack 503 is patterned to form mesa structures of a plurality of semiconductor devices 110. Then, a lower electrode 115′ is formed on the top surface of the mesa structure of the semiconductor devices 110, and a protective layer 118 is conformally formed on the sidewalls of the mesa structure, wherein the protective layer 118 has an opening exposing the lower electrode 115′.

Continuing to refer to FIG. 11, in the step S303, the carrier 101 having a conductive layer 103 formed thereon is provided, and the conductive layer 103 is bonded to the semiconductor stack 503 through the adhesive portion 203. In this configuration, the lower electrode 115′ of the semiconductor device 110 is in direct contact with the conductive layer 103, and the adhesive portion 203 fills the spaces between the mesa structures.

Still referring to FIG. 11, in the step S305, the structure illustrated in the step S303 is flipped upside down, and a laser lift-off (LLO) process is performed by irradiating the laser light from the back side of the wafer 501 to dissociate the semiconductor material between the wafer 501 and the semiconductor stack 503, thereby separating the wafer 501 from the semiconductor stack 503. Then, the semiconductor stack 503 is thinned and patterned to form the semiconductor stacks 111 of the plurality of semiconductor devices 110. The plurality of semiconductor devices 110 are laterally separated from each other, and the protective layer 118 and the adhesive portion 203 surround part of the sidewalls of the semiconductor stack 111. The adhesive portion 203 covers the first region A1 of the continuous surface 103S of the conductive layer 103 and the second region A2 is exposed. Thereafter, an upper electrode 113′ and a conductive bump 117 are formed on the semiconductor stack 111, thereby completing the semiconductor test structure 100C. The first probe 201 and the second probe 202 are used to contact the conductive bump 117 of the semiconductor device 110 and the second region A2 of the conductive layer 103 exposed from the adhesive portion 203, respectively, to perform the electroluminescence measurement.

According to the above embodiments, after the electroluminescence measurement of the semiconductor test structures 100A, 100B, and 100C is completed, a transfer process may subsequently be performed to transfer each semiconductor device 110 in the semiconductor test structures 100A, 100B, and 100C to another carrier, thereby grouping the semiconductor devices 110 with similar or identical electrical or optical specifications. For example, a laser lift-off process may be used to irradiate the laser light from the back side of the carrier 101 onto a selected semiconductor device 110 (e.g., the first semiconductor device 110-1) to decompose or vaporize the adhesive portion 203 between the semiconductor device 110 and the carrier 101, thereby separating the semiconductor device 110 from the carrier 101. The unselected semiconductor devices 110 are not irradiated by the laser light and remain disposed on the front side of the carrier 101. In the subsequent processes, other selected semiconductor devices 110 (e.g., the second semiconductor device 110-2) may be transferred from the carrier 101 to another carrier (not shown), and the transfer process is repeated until all semiconductor devices 110 on the carrier 101 are transferred to the selected identical and/or different carriers.

The foregoing description is merely exemplary embodiments of the present invention, and any equivalent changes and modifications made in accordance with the scope of the claims of the present invention shall fall within the scope of the present invention.

What is claimed is:

1. A semiconductor testing structure, including:
a carrier;
a conductive layer, disposed on the carrier, and including a continuous surface with a first region and a second region;
a first adhesive portion and a second adhesive portion, disposed on the conductive layer in a configuration of covering the first region and exposing the second region; and
a first semiconductor device and a second semiconductor device, disposed on the first adhesive portion and the second adhesive portion, respectively,
wherein the first semiconductor device includes a first lower electrode, a first semiconductor stack and a first upper electrode, in a cross-sectional view, the first lower electrode faces the first adhesive portion, the first upper electrode faces away from the first adhesive portion.

2. The semiconductor testing structure according to claim 1, wherein the carrier is transmittable to light emitted from the first semiconductor device.

3. The semiconductor testing structure according to claim 1, wherein the continuous surface has a portion which is located between the first semiconductor device and the second semiconductor device.

4. The semiconductor testing structure according to claim 1, wherein the first semiconductor device and the second semiconductor device are separated from each other in the cross-sectional view.

5. The semiconductor testing structure according to claim 1, wherein the first semiconductor device further includes a conductive bump disposed between the first lower electrode and the conductive layer.

6. The semiconductor testing structure according to claim 5, wherein the conductive bump comprises a convex portion protruding toward the conductive layer.

7. The semiconductor testing structure according to claim 1, wherein, in the cross-sectional view, the first semiconductor stack has a sidewall which is not directly connected to the first adhesive portion.

8. The semiconductor testing structure according to claim 1, wherein the first lower electrode includes a transparent layer disposed between the first semiconductor stack and the conductive layer, the transparent layer is embedded in the first adhesive portion and directly contacts the conductive layer.

9. The semiconductor testing structure according to claim 8, wherein, in the cross-sectional view, the first semiconductor stack has a sidewall directly connected to the first adhesive portion.

10. The semiconductor testing structure according to claim 1, further including an adhesive layer disposed between the conductive layer and the carrier.
